(19) United States
(12) Patent Application Publication
(10) Pub. No.: US 2024/0395645 A1
(43) Pub. Date: Nov. 28, 2024

(54) Power Amplifier System in a Package

(71) Applicant: 3D Glass Solutions, Inc., Albuquerque, NM (US)

(72) Inventors: Jeb H. Flemming, Albuquerque, NM (US); Kyle McWethy, Albuquerque, NM (US); Cynthia Blair, Morgan Hill, CA (US); Robert D. Hulsman, Littleton, CO (US); Matthew C. Heidel, Cedar Crest, NM (US)

(21) Appl. No.: 18/688,533

(22) PCT Filed: Sep. 2, 2022
(86) PCT No.: PCT/US2022/042516

§ 371 Date: Mar. 1, 2024

Related U.S. Application Data
(60) Provisional application No. 63/240,594, filed on Sep. 3, 2021.

(51) Int. Cl. H01L 23/15; H01L 21/48; H01L 23/08; H01L 25/16; H01L 29/20; H03F 3/24

(52) U.S. Cl. CPC H01L 23/15; H01L 21/4857; H01L 23/08; H01L 25/165; H01L 28/10; H01L 28/20; H01L 28/86; H01L 28/90; H03F 3/245; H01L 21/486; H01L 29/2003; H03F 2200/451

(57) ABSTRACT

The present invention includes a radio frequency power amplifier (RF PA) system-in-a-package (SiP) device including a substrate comprising one or more inductors, capacitors, and thin film resistors wherein the one or more are formed in, on, or about the substrate; an opening in the substrate comprising an iron core, wherein the iron core is formed in the substrate after the formation is create a RF PA SiP in the substrate; and one or more connectors, vias, resistors, capacitors, or other integrated circuits devices connected to create the RF PA SiP.

### CROSS-REFERENCE TO RELATED APPLICATIONS

This application claims the priority to U.S. Provisional Application No. 63/240,594 filed on Sep. 3, 2022, the contents of which are incorporated by reference herein.

### STATEMENT OF FEDERALLY FUNDED RESEARCH

None.

### TECHNICAL FIELD OF THE INVENTION

The present invention relates in general to the field of integrated power amplifier (PA)/integrated passive device (IPD) in/on glass for enhanced performance in radio frequency (RF) applications.

### BACKGROUND OF THE INVENTION

Without limiting the scope of the invention, its background is described in connection with RF circulators.

### SUMMARY OF THE INVENTION

In one embodiment, the present invention can include a radio frequency power amplifier (RF PA) system-in-a-package (SiP) device comprising, consisting essentially of, or consisting of: a substrate comprising one or more inductors, capacitors, and thin film resistors wherein the one or more are formed in, on, or about the substrate; an opening in the substrate comprising an iron core, wherein the iron core is formed in the substrate after the formation is create a RF PA SiP in the substrate; and one or more connectors, vias, resistors, capacitors, or other integrated circuits devices connected to create the RF PA SiP. In one aspect, the one or more inductive devices are one or more conductive coils that comprise copper. In another aspect, the one or more capacitive devices are one or more high surface area shunt capacitors. In another aspect, the one or more high surface area shunt capacitors comprise copper pillars coated with a thin film dielectric material and layer of copper. In another aspect, the one or more resistive devices comprise one or more high surface area shunt capacitors. In another aspect, the one or more high surface area shunt capacitors are formed using a thin film deposition technique. In another aspect, the one or more high surface area shunt capacitors comprise thin films of TiN. In another aspect, the RF PA SiP device has a reduced signal loss when compared to an RF PA glass ceramic SiP. In another aspect, the RF PA SiP device has a loss of less than 50, 40, 30, 25, 20, 15, or 10% of the signal input versus a signal output. In another aspect, the RF PA SiP device has filters with a center frequency shift of less than 80, 75, 70, 60, 50, 40, 30, 25, 20, 15, or 10 MHz. In another aspect, the substrate is glass. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide. In another aspect, the method further comprises coating or depositing a passivation or coating on the RF PA SiP device to protect the RF PA SiP device from an environment. In another aspect, wherein the connectors comprise copper, which can be connector coils. In another aspect, the RF PA SiP device has a reduced signal loss when compared to existing RF PA glass ceramic SiP. In another aspect, the RF PA SiP device has a loss of less than 50, 40, 30, 25, 20, 15, or 10% of the signal input versus a signal output. In another aspect, the iron core comprises melted or sintered iron particles, microparticles, or nanoparticles. In another aspect, a geometry of the RF PA SiP device is substantially circular. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, the present invention can include a radio frequency power amplifier (RF PA) system-in-a-package (SiP) device made by a method comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include a method of making a radio frequency power amplifier (RF PA) system-in-a-package (SiP) device comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include a method for fabricating of a RF PA SiP on or in a glass ceramic comprising, consisting essentially of, or consisting of: obtaining a bottom layer or integrated passive device (IPD) base or substrate; exposing, baking, and etching one or more first through glass vias (TGVs); exposing and baking a high density (HD) capacitor cavity; filling the first TGVs with a metal; double side polish the substrate to a final thickness; patterning and depositing a first topside metal; depositing SiN on top of the first topside metal to form an insulator for a Metal-Insulator-Metal (MIM) capacitor; patterning and etching SiN to remove unwanted SiN from the substrate; depositing on a topside and a backside of the substrate a first metal plating base; patterning a photoresist on the topside and backside of the substrate; electroplating a second metal layer on the topside and backside of the substrate, wherein the second metal layer is thicker than the first metal plating base; removing the photoresist and etching the metal plating base; coating a third metal layer by Electroless Nickel Immersion Gold (ENIG) on the first substrate; etching a high density capacitor cavity in the first substrate; patterning and coating high density capacitor copper pillars with a dielectric layer; patterning and coating the high density capacitor dielectric with a fourth metal layer to make a MIM high density capacitor; obtaining a top layer, lid, or second substrate; exposing, baking, and etching one or more second TGVs in the second substrate; filling the second TGVs in the second substrate with metal; polishing both sides of the second substrate to a final thickness; depositing on a topside and a backside of the second substrate a metal plating base; patterning a photoresist on the metal plating base on the topside and backside of the second substrate; electroplating a fifth copper metal layer on the topside and backside of the second substrate; removing the photoresist and etching a second metal plating base; coating a sixth copper metal layer with ENIG; and bonding the first substrate to the second substrate using solder, adhesives, or Au/Au thermosonic bonding. In one aspect, the metal is copper, silver, gold, platinum, titanium, aluminum, or alloys thereof. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to an unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, the present invention can include a radio frequency integrated system-in-a-package (SiP) device comprising with the RF filter monolithically integrated into the source or drain contact of the GaN transistor comprising, consisting essentially of, or consisting of: a substrate comprising one or more inductors, capacitors, and thin film resistors wherein the one or more are formed in, on, or about the substrate; and one or more connectors, vias, resistors, inductors, capacitors, or other integrated circuits devices connected to create the RF integrated SiP. In one aspect, the one or more inductors are one or more conductive coils that comprise copper. In another aspect, the one or more capacitors are one or more high surface area shunt capacitors. In another aspect, the one or more MIM capacitors are one or more high surface area shunt capacitors. In another aspect, the one or more high surface area shunt capacitors comprise semiconductor doped conductive pillars coated with a thin film dielectric material and layer of copper. In another aspect, the one or more high surface area shunt capacitors comprise copper pillars coated with a thin film dielectric material and layer of copper. In another aspect, the one or more resistors comprise one or more high surface area shunt capacitors. In another aspect, the one or more high surface area shunt capacitors are formed using a thin film deposition technique. In another aspect, the one or more high surface area shunt capacitors comprise thin films of SiN or other dielectric material. In another aspect, the RF PA SiP device has a reduced signal loss when compared to an RF PA glass ceramic SiP. In another aspect, the RF integrated SiP device has a loss of less than 50, 40, 30, 25, 20, 15, or 10% of a signal input versus a signal output. In another aspect, the RF PA SiP device has filters with a center frequency shift of less than 80, 75, 70, 60, 50, 40, 30, 25, 20, 15, or 10 MHz. In another aspect, the substrate is glass. In another aspect, the RF PA SiP device increases bandwidth the video/communications bandwidth a minimum 10% to greater than 300%. In another aspect, the substrate is a photosensitive glass ceramic composite substrate comprising at least silica, lithium oxide, aluminum oxide, and cerium oxide. In another aspect, the radio frequency integrated system-in-a-package (SiP) device further includes a passivation or coating layer on the RF PA SiP device to protect the RF PA SiP device from an environment. In another aspect, the connectors comprise copper, which can be connector coils. In another aspect, the RF PA SiP device has a reduced signal loss when compared to existing RF PA glass ceramic SiP. In another aspect, the RF PA SiP device has a loss of less than 50, 40, 30, 25, 20, 15, or 10% of a signal input versus a signal output. In another aspect, a geometry of the RF PA SiP device is substantially circular. In another aspect, the iron core comprises melted or sintered iron particles, microparticles, or nanoparticles.

In another embodiment, the present invention can include a radio frequency power amplifier (RF PA) system-in-a-package (SiP) device made by a method comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include a method of making a radio frequency power amplifier (RF PA) system-in-a-package (SiP) device comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include method for fabricating of a RF PA SiP on or in a glass ceramic comprising, consisting essentially of, or consisting of: obtaining a bottom layer or integrated passive device (IPD) base or first substrate; exposing, baking, and etching one or more first through glass vias (TGVs); exposing and baking a high density (HD) capacitor cavity; filling the first TGVs with a metal; double side polishing the substrate to a final thickness; patterning and depositing a first topside metal; depositing SiN on top of the first topside metal to form an insulator for a Metal-Insulator-Metal (MIM) capacitor; patterning and etching SiN to remove unwanted SiN from the substrate; depositing on a topside and a backside of the substrate a first metal plating base; patterning a photoresist on the topside and backside of the substrate; electroplating a second metal layer on the topside and backside of the substrate, wherein the second metal layer is thicker than the first metal plating base; removing the photoresist and etching the metal plating base; coating a third metal layer by Electroless Nickel Immersion Gold (ENIG) on the first substrate; etching a high density capacitor cavity in the first substrate; patterning and coating high density capacitor copper pillars with a dielectric layer; patterning and coating the high density capacitor dielectric with a fourth metal layer to make a MIM high density capacitor; obtaining a top layer, lid, or second substrate; exposing, baking, and etching one or more second TGVs in the second substrate; filling the second TGVs in the second substrate with metal; polishing both sides of the second substrate to a final thickness; depositing on a topside and a backside of the second substrate a metal plating base; patterning a photoresist on the metal plating base on the topside and backside of the second substrate; electroplating a fifth copper metal layer on the topside and backside of the second substrate; removing the photoresist and etching a second metal plating base; coating a sixth copper metal layer with ENIG; and bonding the first substrate to the second substrate using solder, adhesives, or Au/Au thermosonic bonding. In one aspect, the metal is copper, silver, gold, platinum, titanium, aluminum, or alloys thereof. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to an unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

### BRIEF DESCRIPTION OF THE DRAWINGS

For a more complete understanding of the features and advantages of the present invention, reference is now made to the detailed description of the invention along with the accompanying figures and in which:

FIG. 1A shows a shift in the frequency and a collapse of the signal to noise for a traditional radio frequency power amplifier (RF PA) SiP.

FIG. 1B shows the enhanced performance of a photodefinable glass-based RF PA SiP of the present invention.

FIG. 2 shows a schematic for a photodefinable glass RF PA SiP of the present invention.

FIG. 3 shows a diagram of the electrical elements of an integration SiP using wire bonds to connect semiconductor device(s) to IPDs.

FIG. 4 shows a shift in the frequency of the signal from 300 MHz to 900 MHz.

FIG. 5A shows one possible configuration with the SMT High Density Capacitor placed on top of the metal contact of the Drain/Source of the GaN.

FIG. 5B shows a cross section with the SMT High Density Capacitor placed on top of the metal contact of the Drain/Source of the GaN.

FIG. 6 shows a second configuration with the SMT-High Density Capacitor placed on bottom of the metal contact of the Drain/Source of the GaN.

FIG. 7 shows the placement of the RF Filter in/on the source or drain of the GaN amplifier of the RF SiP.

FIG. 8A shows a traditional RF Amplifier with no integrated filter in the SiP.

FIG. 8B shows an RF Amplifier with placement of the RF filter on the contact for the Source side of the GaN Amplifier.

FIG. C shows an RF Amplifier with placement of the RF filter on the contact for the Drain side of the GaN Amplifier.

FIG. 9 shows a drawing of integration of SiP using wire bonds to connect semiconductor device(s) to IPDs. Where the semiconductor can be a power amplifier or other semiconductor device.

FIG. 10 shows power amplifier of other semiconductor element with metalized Kapton™ replacement for bonding wire connectors to create a SiP.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims.

Modern radio frequency power amplifier (rf power amplifier or RF PA) is a type of semiconductor-based amplifier that converts a low-power radio-frequency signal into a higher power signal. RF power amplifiers are used to drive the antenna of a transmitter in a wide array of modern communication systems. Design goals often include gain, power output, bandwidth, power efficiency, linearity (low signal compression at rated output), input and output impedance matching, and heat dissipation. Commercially available RF PAs have a number of passive and active components/elements with a larger cost including; Copper flanges $10; Lid—$0.25; IPDIA HD Cap—$2.00. The assembly is a traditional commercially available RF PAs use wire bonded; plastic or epoxy overmold. Traditional overmolding general has air bubble and induces parasitic losses that can shift the center frequency of the bandpass filters by as much as 80 MHz.

Semiconductor RF PA performance has been driven more recent years by the introduction of Gallium Nitride (GaN) transistors. GaN have lead the advancement in the scaling of monolithic microwave integrated circuit (MMIC) leading to highly integrated performance Systems in a Package (SiP) technology. RF PA based SIPs are typically used in microwave power amplification and low-noise amplification. Inputs and outputs on MMIC devices are frequently matched to a characteristic impedance of 50 ohms. GaN transistors have enabled compact SiPs as they can operate at much higher temperatures and voltages making them ideal power amplifiers operating at microwave frequencies from 300 MHz to 300 GHz.

RF PA glass ceramic SiP of the present invention can be used for devices and arrays in glass ceramic substrates for electronic, microwave and radiofrequency in general. In one embodiment, the present invention includes a RF PA SiP comprising: a substrate comprising one or more conductive coils, wherein the one or more conductive coils are formed in, on, or about the substrate; in conjunction with thin film and/or high surface area capacitors and thin film resistors comprising passive device for the RF PA SiP. The passive devices are integrated by one or more connectors, vias, inductors, resistors, capacitors, or other integrated circuits of enabling an RF PA SiP in photodefinable glass substrate.

RF PA SiPs enable multiple-input and multiple-output (MIMO) communications. MIMO is a method for multiplying the capacity of a RF links using multiple transmission and receiving antennas to achieve multipath RF frequencies. MIMO is an essential element of RF wireless communication. MIMO refers to a technique for sending and receiving multiple data signals simultaneously over the same radio channel by exploiting multipath propagation or frequencies. Although this “multipath” phenomenon may be interesting, it's the use of orthogonal frequency division multiplexing to encode the channels that's responsible for the increase in data capacity. MIMO is fundamentally different from smart antenna techniques developed to enhance the performance of a single data signal, such as beamforming and diversity.

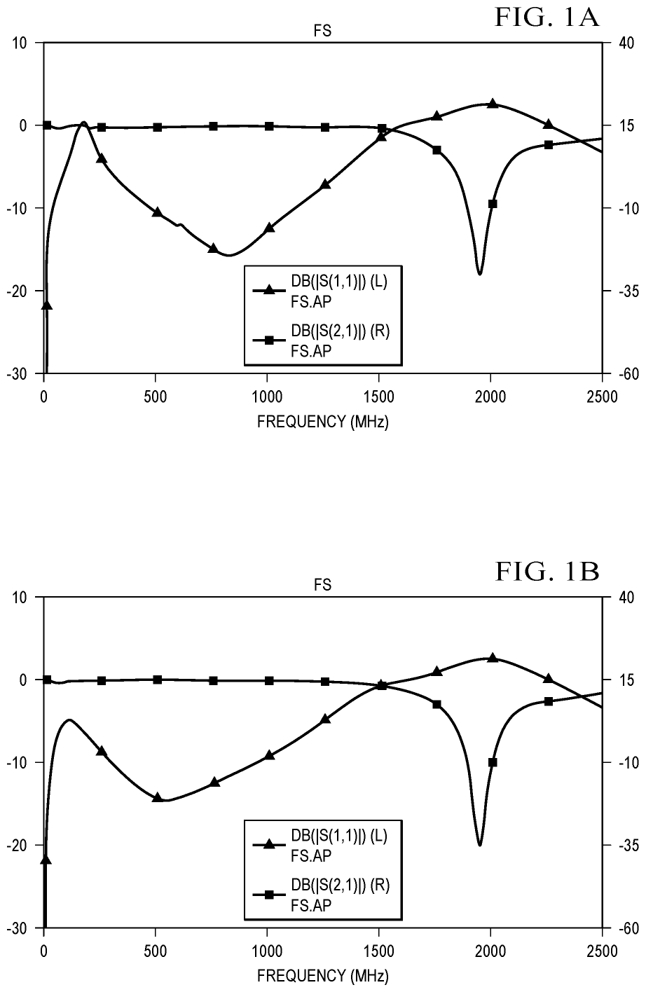

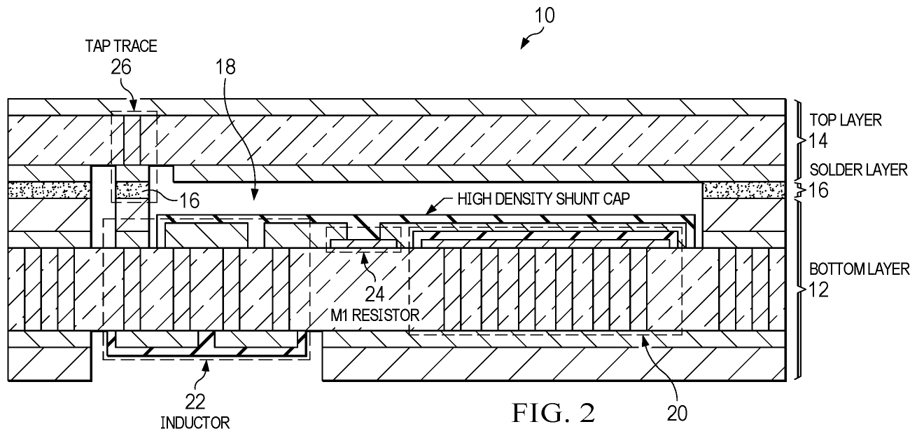

In another aspect, the RF PA SiP in photodefinable glass substrate has a loss of less than 50, 40, 30, 25, 20, 15, or 10% of the signal input versus traditional RF PA. See FIGS. 1A and 1B. In another aspect, geometry of the RF PA SiP device is substantially circular. In another aspect, the substrate is glass. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, an RF PA SiP is made by a method comprising: forming on a substrate one or more conductive coils, wherein the one or more conductive coils are formed in, on, or about the substrate; etching an opening in the substrate; depositing iron particles in the opening; melting or sintering the iron particles into an iron core, wherein the iron core is formed in the substrate after the formation of the one or more conductive coils, wherein the iron core is positioned and shaped to create a RF PA SiP in the substrate; and connecting the conductive coils of the RF PA SiP to, e.g., an amplifier, an inductor, an antenna, a resistor, a capacitor, etc.

The RF PA glass ceramic SiP of the present invention can be used for devices and arrays in glass ceramic substrates for electronic, microwave and radiofrequency in general. This invention provides creates a cost-effective glass ceramic inductive individual or array device. Where glass ceramic substrate has demonstrated capability to form such structures through the processing of both the vertical as well as horizontal planes either separately or at the same time to form RF PA glass ceramic SiP that can be used in a wide variety of telecommunications and other platforms. The novel RF PA glass ceramic SiP can be made as stand-alone or add to other devices, can be built into a substrate directly and then connected to other electronic components using vias, wire or ball bonding, etc.

In one embodiment, the present invention is a RF PA SiP built for an integrated passive device (IPD) that has a decreased size versus currently available options. The test vehicle can include, e.g., one or more types of glass made and formulated as described hereinbelow obtained from, e.g., 3DGS, USA, with methods and parts for improved by iron core filling. First, a standard cavity depth will be used to ensure consistent measurement. Next, components that are formed, added or connected to form a circuit are connected to the RF PA SiP and are then evaluated as testing proceeds and specific volumes are necessary for accurate calculations.

FIG. 2 shows an RF PA glass ceramic SiP 10 of the present invention. The present invention includes a method of fabrication a RF PA SiP 10, which includes a bottom layer 12, a top layer 14 and is shown interconnected mechanically and/or electrically by layer 14. Layer 16 can be electrically conductive, such as, e.g., a solder layer, metal layer, conductive polymer or conductive adhesive, or Au/Au thermosonic bonding. The bottom layer 12 and top layer 14 are separated by an opening or gap 18. In this embodiment, the bottom layer 12 is shown with three difference devices that are formed in and/or on the bottom layer 12: a high density shunt capacitor 20, an inductor 22, and an M1 resistor 24. The inductor 22 is shown connected to a tap trace 26, which is connected with layer 16, which in this instance is a solder layer.

The RF PA glass ceramic SiP is made by preparing a photosensitive glass ceramic composite substrate comprising at least silica, lithium oxide, aluminum oxide, and cerium oxide. The RF PA SiP is formed in the glass ceramic the photosensitive glass ceramic composite substrate by masking a design layout comprising one or more, two or three dimensional inductive device in the photosensitive glass substrate, exposing at least one portion of the photosensitive glass substrate to an activating energy source, exposing the photosensitive glass substrate to a heating phase of at least ten minutes above its glass transition temperature, cooling the photosensitive glass substrate to transform at least part of the exposed glass to a crystalline material to form a glass-crystalline substrate and etching the glass-crystalline substrate with an etchant solution to form one or more angled channels or through holes that are then used in the RF PA SiP.

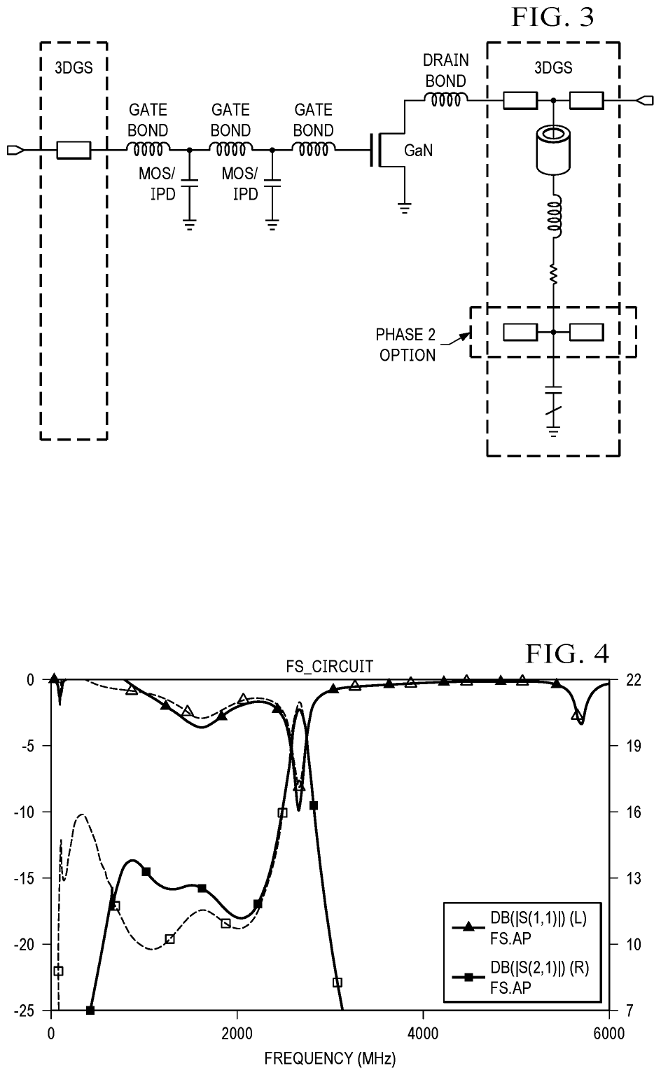

FIG. 3 shows a diagram of the electrical elements of an integration SiP using wire bonds to connect semiconductor device(s) to IPDs.

The RF PA SiP can be built in, on, or about a glass ceramic (APEX® Glass Ceramic™, 3DGS, USA) as a novel packaging and substrate material for semiconductors, RF electronics, microwave electronics, and optical imaging. APEX® Glass ceramic is processed using first generation semiconductor equipment in a simple three step process and the final material can be fashioned into either glass, ceramic, or contain regions of both glass and ceramic. The APEX® Glass ceramic possesses several benefits over current materials, including: easily fabricated high density vias, demonstrated microfluidic capability, micro-lens or micro-lens array, high Young's modulus for stiffer packages, halogen free manufacturing, and economical manufacturing. Photoetchable glasses have several advantages for the fabrication of a wide variety of microsystems components. Microstructures have been produced relatively inexpensively with these glasses using conventional semiconductor processing equipment. In general, glasses have high temperature stability, good mechanical and electrically properties, and have better chemical resistance than plastics and many metals. One example of a glass ceramic for making the RF PA SiP of the present invention includes, for example, silicon oxide (SiO₂) of 75-85% by weight, lithium oxide (Li₂O) of 7-11% by weight, aluminum oxide (Al₂O₃) of 3-6% by weight, sodium oxide (Na₂O) of 1-2% by weight, 0.2-0.5% by weight antimonium trioxide (Sb₂O₃) or arsenic oxide (As₂O₃), silver oxide (Ag₂O) of 0.05-0.15% by weight, and cerium oxide (CeO₂) of 0.01-0.04% by weight. As used herein the terms “APEX® Glass ceramic”, “APEX® glass” or simply “APEX®” are used to denote one embodiment of the glass ceramic composition for making the RF PA SiP of the present invention.

The present invention includes an RF PA SiP created in the multiple planes of a glass-ceramic substrate, such process employing the: (a) exposure to excitation energy such that the exposure occurs at various angles by either altering the orientation of the substrate or of the energy source, (b) a bake step and (c) an etch step. Angle sizes can be either acute or obtuse. The curved and digital structures are difficult, if not infeasible to create in most glass, ceramic or silicon substrates. The present invention has created the capability to create such RF PA SiP structures in both the vertical as well as horizontal plane for glass-ceramic substrates. The present invention includes a method for fabricating of a RF PA SiP on or in a glass ceramic by:
Start with a bottom layer or integrated passive device (IPD) base or substrate.
Expose, bake, and etch the through glass vias (TGVs).
Expose and bake a high density (HD) capacitor cavity.
Fill TGVs with a metal. A metal for use with the present invention can be, e.g., copper, silver, gold, platinum, titanium, aluminum, and/or alloys thereof.
Double side polish wafer to final thickness.
Pattern and deposit topside metal 1 (e.g., 1 μm thick copper).
Deposit SiN on top of topside metal 1 (insulator for Metal-Insulator-Metal (MIM) capacitor).
Pattern and Etch SiN to remove unwanted SiN from the bottom layer or IPD base or substrate.
Deposit topside and backside metal plating base.
Pattern Photoresist on both sides.
Electroplate thick copper metal 2 (e.g., 20 μm) on both sides.
Remove photoresist and etch Cu plating base.
Coat Thick metal 2 layer with Electroless Nickel Immersion Gold (ENIG).
Etch High density capacitor cavity.
Pattern and coat High density capacitor Cu pillars with a dielectric layer.
Pattern and coat high density capacitor dielectric with 2nd metal layer to make MIM high density cap.
Start with a top layer or lid.
Expose, bake, etch TGVs.
Fill TGVs with metal. A metal for use with the present invention can be, e.g., copper, silver, gold, platinum, titanium, aluminum, and/or alloys thereof.
Double side polish wafer to final thickness.
Deposit topside and backside metal plating base.
Pattern Photoresist on both sides.
Electroplate thick copper metal 2 (e.g., 20 μm) on both sides.
Remove photoresist and etch metal plating base.
Coat Thick metal 2 layer with ENIG.
Bond IPD base and lid together using solder or Au/Au thermosonic bonding.

Ceramicization of the glass is accomplished by exposing the entire glass substrate to approximately 20 J/cm² of 310 nm light. When trying to create glass spaces within the ceramic, users expose all of the material, except where the glass is to remain glass. In one embodiment, the present invention can use, e.g., a quartz/chrome mask containing the various components of the RF PA SiP, e.g., the coil(s), connectors or electrical conductor(s), capacitor(s), resistor(s), ferrous and/or ferromagnetic component(s), etc.

Test and validation of the RF PA SiP. The product design will incorporate both SMT and probe-launched circulator structures. The RF PA SiP can be made with surface mount technologies (SMT) devices that can be soldered directly onto a printed circuit board (PCB), or something similar, test board that will be capable of 3-port testing of the RF performance of the circulator and de-embedding the connectors and test boards to validate the de-embedded performance of the circulator. The present inventors have developed a set of low-loss SMT launches and board-level calibration standards which will be leveraged for this portion of the work. A probe-launch circulator device with probe launch design and on-wafer calibration structures can be validated as low-loss test and calibration structures from 0.5-40 GHz. For example, a 250 μm pitch ground-signal-ground (GSG) probes enable on wafer 3-port measurement of the circulator as an integrated passive device, which is designed and laid out as described herein.

One non-limiting example of a substrate for use with the RF PA SiP device present invention includes, e.g., a glass micromachined with etch ratios of 30:1 or more using a mid-ultraviolet flood exposure system and potentially 40:1 or more (preferably 50:1 or more) using a laser-based exposure system, to produce high-precision structures. Thus, for example, with nearly vertical wall slopes on both the inside and outside diameters of hollow photostructured microneedles only minor wall-thickness variation from tip to base would occur. In addition, microposts, which are non-hollow microneedles, may be micromachined to possess a low wall slope, enabling a decrease in the overall micropost diameter. Likewise, micro-lenses can be shaped with precisely controlled horizontal variations and have only minor vertical variation.

In one embodiment, the RF PA SiP device of the present invention is essentially germanium-free. In some embodiments, Sb₂O₃ or As₂O₃ is added (e.g., at least 0.3 weight percent (weight %) Sb₂O₃ or As₂O₃) to help control the oxidation state of the composition. In some preferred embodiments, at least 0.75 weight % B₂O₃ is included, and in others at least 1.25 weight % B₂O₃ is included. In some preferred embodiments, at least 0.003% Au₂O is included in addition to at least 0.003 weight % Ag₂O. In some embodiments, a combination of CaO and/or ZnO is added up to 18 weight %. In some embodiments, up to 10 weight % MgO is added. In some embodiments, up to 18 weight % lead oxide is added. Up to 5 weight %, Fe₂O₃, may be added to make the material paramagnetic and iron (II) and iron (III) may be added as a quenching agent to reduce autofluorescence of the glass.

In certain instances, the glass substrate is heated to a temperature of 420-520° C. for between 10 minutes and 2 hours and then heated to a temperature range heated to 520-620° C. for between 10 minutes and 2 hours.

In one embodiment, the present invention can include a radio frequency power amplifier (RF PA) system-in-a-package (SiP) device comprising, consisting essentially of, or consisting of: a substrate comprising one or more inductors, capacitors, and thin film resistors wherein the one or more are formed in, on, or about the substrate; an opening in the substrate comprising an iron core, wherein the iron core is formed in the substrate after the formation is create a RF PA SiP in the substrate; and one or more connectors, vias, resistors, capacitors, or other integrated circuits devices connected to create the RF PA SiP. In one aspect, the one or more inductive devices are one or more conductive coils that comprise copper. In another aspect, the one or more capacitive devices are one or more high surface area shunt capacitors. In another aspect, the one or more high surface area shunt capacitors comprise copper pillars coated with a thin film dielectric material and layer of copper. In another aspect, the one or more resistive devices comprise one or more high surface area shunt capacitors. In another aspect, the one or more high surface area shunt capacitors are formed using a thin film deposition technique. In another aspect, the one or more high surface area shunt capacitors comprise thin films of TiN. In another aspect, the RF PA SiP device has a reduced signal loss when compared to an RF PA glass ceramic SiP. In another aspect, the RF PA SiP device has a loss of less than 50, 40, 30, 25, 20, 15, or 10% of the signal input versus a signal output. In another aspect, the RF PA SiP device has filters with a center frequency shift of less than/greater than 50, 40, 30, 25, 20, 15, or 10 MHz. In another aspect, the substrate is glass. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide. In another aspect, the method further comprises coating or depositing a passivation or coating on the RF PA SiP device to protect the RF PA SiP device from an environment. In another aspect, the conductive coils comprise copper. In another aspect, the RF PA SiP device has a reduced signal loss when compared to existing RF PA glass ceramic SiP. In another aspect, the RF PA SiP device has a loss of less than 50, 40, 30, 25, 20, 15, or 10% of the signal input versus a signal output. In another aspect, the iron core comprises melted or sintered iron particles, microparticles, or nanoparticles. In another aspect, a geometry of the RF PA SiP device is substantially circular. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, the present invention can include a radio frequency power amplifier (RF PA) system-in-a-package (SiP) device made by a method comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include a method of making a radio frequency power amplifier (RF PA) system-in-a-package (SiP) device comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF PA SiP to an antenna.

In another embodiment, the present invention can include a method for fabricating of a RF PA SiP on or in a glass ceramic comprising, consisting essentially of, or consisting of: obtaining a bottom layer or integrated passive device (IPD) base or substrate; exposing, baking, and etching one or more first through glass vias (TGVs); exposing and baking a high density (HD) capacitor cavity; filling the first TGVs with a metal; double side polish the substrate to a final thickness; patterning and depositing a first topside metal; depositing SiN on top of the first topside metal to form an insulator for a Metal-Insulator-Metal (MIM) capacitor; patterning and etching SiN to remove unwanted SiN from the substrate; depositing on a topside and a backside of the substrate a first metal plating base; patterning a photoresist on the topside and backside of the substrate; electroplating a second metal layer on the topside and backside of the substrate, wherein the second metal layer is thicker than the first metal plating base; removing the photoresist and etching the metal plating base; coating a third metal layer by Electroless Nickel Immersion Gold (ENIG) on the first substrate; etching a high density capacitor cavity in the first substrate; patterning and coating high density capacitor copper pillars with a dielectric layer; patterning and coating the high density capacitor dielectric with a fourth metal layer to make a MIM high density capacitor; obtaining a top layer, lid, or second substrate; exposing, baking, and etching one or more second TGVs in the second substrate; filling the second TGVs in the second substrate with metal; polishing both sides of the second substrate to a final thickness; depositing on a topside and a backside of the second substrate a metal plating base; patterning a photoresist on the metal plating base on the topside and backside of the second substrate; electroplating a fifth copper metal layer on the topside and backside of the second substrate; removing the photoresist and etching a second metal plating base; coating a sixth copper metal layer with ENIG; and bonding the first substrate to the second substrate using solder, adhesives, or Au/Au thermosonic bonding.

In some embodiments, the etchant is HF, in some embodiments the etchant is a combination of HF and additional ingredients, such as hydrochloric acid or nitric acid. The preferred wavelength of the ultraviolet light used for exposure is approximately 308-312 nm.

Modern radio frequency power amplifier (rf power amplifier or RF PA) is a type of semiconductor-based amplifier that converts a low-power radio-frequency signal into a higher power signal. RF power amplifiers are used to drive the antenna of a transmitter in a wide array of modern communication systems. Design goals often include gain, power output, bandwidth, power efficiency, linearity (low signal compression at rated output), input and output impedance matching, and heat dissipation. Commercially available RF PAs have a number of passive and active components/elements with a larger cost including; Copper flanges $10; Lid—$0.25; IPDIA HD Cap—$2.00. The assembly is a traditional commercially available RF PAs use wire bonded; plastic or epoxy overmold. Traditional overmolding general has air bubble and induces parasitic losses that can shift the center frequency of the bandpass filters by as much as 80 MHz.

Semiconductor RF PA performance has been driven more recent years by the introduction of Gallium Nitride (GaN) transistors. GaN have led the advancement in the scaling of monolithic microwave integrated circuit (MMIC) leading to highly integrated performance Systems in a Package (SiP) technology. RF PA based SIPs are typically used in microwave power amplification and low-noise amplification. Inputs and outputs on MMIC devices are frequently matched to a characteristic impedance of 50 ohms. GaN transistors have enabled compact SiPs as they can operate at much higher temperatures and voltages making them ideal power amplifiers operating at microwave frequencies from 300 MHz to 300 GHz.

Glass ceramic integrated SiP of the present invention can be used for devices and arrays in glass ceramic substrates for electronic, microwave and radiofrequency in general. In one embodiment, the present invention includes an integrated SiP comprising: a substrate comprising one or more conductive coils, wherein the one or more conductive coils are formed in, on, or about the substrate; in conjunction with thin film and/or high surface area capacitors and thin film resistors comprising passive device for the RF PA integrated SiP. The passive devices are integrated by one or more connectors, vias, inductors, resistors, capacitors, or other integrated circuits of enabling an RF PA integrated SiP in photodefinable glass or other substrate.

RF PA integrated SiP enable multiple-input and multiple-output (MIMO) communications. MIMO is a method for multiplying the capacity of a RF links using multiple transmission and receiving antennas to achieve multipath RF frequencies. MIMO is an essential element of RF wireless communication. MIMO refers to a technique for sending and receiving multiple data signals simultaneously over the same radio channel by exploiting multipath propagation or frequencies. Although this “multipath” phenomenon may be interesting, it's the use of orthogonal frequency division multiplexing to encode the channels that's responsible for the increase in data capacity. MIMO is fundamentally different from smart antenna techniques developed to enhance the performance of a single data signal, such as beamforming and diversity.

In another aspect, the RF PA integrated SiP in photodefinable glass substrate has a loss of less than 50, 40, 30, 25, 20, 15, or 10% of the signal input versus traditional RF PA. See FIGS. 1A and 1B. In another aspect, geometry of the RF PA SiP device is substantially circular. In another aspect, the substrate is glass. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, an RF PA SiP is made by a method comprising: forming on a substrate one or more conductive coils, wherein the one or more conductive coils are formed in, on, or about the substrate; etching an opening in the substrate; depositing iron particles in the opening; melting or sintering the iron particles into an iron core, wherein the iron core is formed in the substrate after the formation of the one or more conductive coils, wherein the iron core is positioned and shaped to create a RF PA SiP in the substrate; and connecting the conductive coils of the RF PA SiP to, e.g., an amplifier, an inductor, an antenna, a resistor, a capacitor, etc.

The RF PA glass ceramic SiP of the present invention can be used for devices and arrays in glass ceramic substrates for electronic, microwave and radiofrequency in general. This invention provides creates a cost-effective glass ceramic inductive individual or array device. Where glass ceramic substrate has demonstrated capability to form such structures through the processing of both the vertical as well as horizontal planes either separately or at the same time to form RF PA glass ceramic SiP that can be used in a wide variety of telecommunications and other platforms. The novel RF PA glass ceramic SiP can be made as stand-alone or add to other devices, can be built into a substrate directly and then connected to other electronic components using vias, wire or ball bonding, etc.

In one embodiment, the present invention is a RF PA integrated SiP built for an integrated passive device (IPD) that has a decreased size versus currently available options. The test vehicle can include, e.g., one or more types of glass made and formulated as described hereinbelow obtained from, e.g., 3DGS, USA, with methods and parts for improved by iron core filling. First, a standard cavity depth will be used to ensure consistent measurement. Next, components that are formed, added or connected to form a circuit are connected to the RF integrated SiP and are then evaluated as testing proceeds and specific volumes are necessary for accurate calculations.

The RF PA integrated glass ceramic SiP is made by preparing a photosensitive glass ceramic composite substrate comprising at least silica, lithium oxide, aluminum oxide, and cerium oxide. The RF PA integrated SiP is formed in the glass ceramic the photosensitive glass ceramic composite substrate by masking a design layout comprising one or more, two or three dimensional inductive device in the photosensitive glass substrate, exposing at least one portion of the photosensitive glass substrate to an activating energy source, exposing the photosensitive glass substrate to a heating phase of at least ten minutes above its glass transition temperature, cooling the photosensitive glass substrate to transform at least part of the exposed glass to a crystalline material to form a glass-crystalline substrate and etching the glass-crystalline substrate with an etchant solution to form one or more angled channels or through holes that are then used in the RF PA integrated SiP.

The RF PA integrated SiP can be built in, on, or about a glass ceramic (APEX® Glass Ceramic™, 3DGS, USA) as a novel packaging and substrate material for semiconductors, RF electronics, microwave electronics, and optical imaging. APEX® Glass ceramic is processed using first generation semiconductor equipment in a simple three step process and the final material can be fashioned into either glass, ceramic, or contain regions of both glass and ceramic. The APEX® Glass ceramic possesses several benefits over current materials, including: easily fabricated high density vias, demonstrated microfluidic capability, micro-lens or micro-lens array, high Young's modulus for stiffer packages, halogen free manufacturing, and economical manufacturing. Photoetchable glasses have several advantages for the fabrication of a wide variety of microsystems components. Microstructures have been produced relatively inexpensively with these glasses using conventional semiconductor processing equipment. In general, glasses have high temperature stability, good mechanical and electrically properties, and have better chemical resistance than plastics and many metals. One example of a glass ceramic for making the RF PA SiP of the present invention includes, for example, silicon oxide (SiO₂) of 75-85% by weight, lithium oxide (Li₂O) of 7-11% by weight, aluminum oxide (Al₂O₃) of 3-6% by weight, sodium oxide (Na₂O) of 1-2% by weight, 0.2-0.5% by weight antimonium trioxide (Sb₂O₃) or arsenic oxide (As₂O₃), silver oxide (Ag₂O) of 0.05-0.15% by weight, and cerium oxide (CeO₂) of 0.01-0.04% by weight. As used herein the terms “APEX® Glass ceramic”, “APEX® glass” or simply “APEX®” are used to denote one embodiment of the glass ceramic composition for making the RF PA integrated SiP of the present invention.

The present invention includes an RF PA integrated SiP created in the multiple planes of a glass-ceramic substrate, such process employing the: (a) exposure to excitation energy such that the exposure occurs at various angles by either altering the orientation of the substrate or of the energy source, (b) a bake step and (c) an etch step. Angle sizes can be either acute or obtuse. The curved and digital structures are difficult, if not infeasible to create in most glass, ceramic or silicon substrates. The present invention has created the capability to create such RF PA integrated SiP structures in both the vertical as well as horizontal plane for glass-ceramic substrates. The present invention includes a method for fabricating of a RF PA integrated SiP on or in a glass ceramic flow for the IPD (RF Filter) Base by:
Expose, bake, etch TGVs
Expose and bake HD cap cavity
Fill TGVs with copper
Double side polish wafer to final thickness
Pattern and deposit topside metal 1 (1 μm thick copper)
Deposit SiN on top of topside metal 1 (insulator for MIM cap)
Pattern and Etch SiN to remove unwanted SiN from chip
Deposit topside and backside Cu plating base
Pattern Photoresist on both sides
Electroplate thick copper metal 2 (20 μm) on both sides
Remove photoresist and etch Cu plating base
Coat Thick Cu metal 2 layer with ENIG
Etch High density cap cavity
Pattern & Coat High density cap Cu pillars with dielectric
Pattern and coat high density cap dielectric with 2nd metal layer to make MIM high density cap

The process flow for the IPD (RF Filter) Lid is:
Expose, bake, etch TGVs
Fill TGVs with copper
Double side polish wafer to final thickness
Deposit topside and backside Cu plating base
Pattern Photoresist on both sides
Electroplate thick copper metal 2 (20 μm) on both sides
Remove photoresist and etch Cu plating base
Coat Thick Cu metal 2 layer with ENIG
Bond IPD base and lid together using solder or Au/Au thermosonic bonding.

Ceramicization of the glass is accomplished by exposing the entire glass substrate to approximately 20 J/cm² of 310 nm light. When trying to create glass spaces within the ceramic, users expose all of the material, except where the glass is to remain glass. In one embodiment, the present invention can use, e.g., a quartz/chrome mask containing the various components of the RF PA integrated SiP, e.g., the coil(s), connectors or electrical conductor(s), capacitor(s), resistor(s), ferrous and/or ferromagnetic component(s), etc.

Test and validation of the RF PA integrated SiP. The product design will incorporate both SMT and probe-launched circulator structures. The RF PA integrated SiP can be made with surface mount technologies (SMT) devices that can be soldered directly onto a printed circuit board (PCB), or something similar, test board that will be capable of 3-port testing of the RF performance of the circulator and de-embedding the connectors and test boards to validate the de-embedded performance of the circulator. The present inventors have developed a set of low-loss SMT launches and board-level calibration standards which will be leveraged for this portion of the work. A probe-launch device with probe launch design and on-wafer calibration structures can be validated as low-loss test and calibration structures from 0.5-40 GHz. For example, a 250 μm pitch ground-signal-ground (GSG) probes enable on wafer 3-port measurement of the circulator as an integrated passive device, which is designed and laid out as described herein.

One non-limiting example of a substrate for use with the RF PA integrated SiP device present invention includes, e.g., a glass micromachined with etch ratios of 30:1 or more using a mid-ultraviolet flood exposure system and potentially 40:1 or more (preferably 50:1 or more) using a laser-based exposure system, to produce high-precision structures. Thus, for example, with nearly vertical wall slopes on both the inside and outside diameters of hollow photostructured microneedles only minor wall-thickness variation from tip to base would occur. In addition, microposts, which are non-hollow microneedles, may be micromachined to possess a low wall slope, enabling a decrease in the overall micropost diameter. Likewise, micro-lenses can be shaped with precisely controlled horizontal variations and have only minor vertical variation.

In one embodiment, the RF PA integrated SiP device of the present invention is essentially germanium-free. In some embodiments, Sb₂O₃ or As₂O₃ is added (e.g., at least 0.3 weight percent (weight %) Sb₂O₃ or As₂O₃) to help control the oxidation state of the composition. In some preferred embodiments, at least 0.75 weight % B₂O₃ is included, and in others at least 1.25 weight % B₂O₃ is included. In some preferred embodiments, at least 0.003% Au₂O is included in addition to at least 0.003 weight % Ag₂O. In some embodiments, a combination of CaO and/or ZnO is added up to 18 weight %. In some embodiments, up to 10 weight % MgO is added. In some embodiments, up to 18 weight % lead oxide is added. Up to 5 weight %, Fe₂O₃, may be added to make the material paramagnetic and iron (II) and iron (III) may be added as a quenching agent to reduce autofluorescence of the glass.

In certain instances, the glass substrate is heated to a temperature of 420-520° C. for between 10 minutes and 2 hours and then heated to a temperature range heated to 520-620° C. for between 10 minutes and 2 hours.

In one embodiment, the present invention can include a radio frequency power amplifier (RF PA) integrated SiP device comprising, consisting essentially of, or consisting of: a substrate comprising one or more inductors, capacitors, and thin film resistors wherein the one or more are formed in, on, or about the substrate; an opening in the substrate comprising an iron core, wherein the iron core is formed in the substrate after the formation is create a RF PA integrated SiP in the substrate; and one or more connectors, vias, resistors, capacitors, or other integrated circuits devices connected to create the RF PA integrated SiP. In one aspect, the one or more inductive devices are one or more conductive coils that comprise copper. In another aspect, the one or more capacitive devices are one or more high surface area shunt capacitors. In another aspect, the one or more high surface area shunt capacitors comprise copper pillars coated with a thin film dielectric material and layer of copper. In another aspect, the one or more resistive devices comprise one or more high surface area shunt capacitors. In another aspect, the one or more high surface area shunt capacitors are formed using a thin film deposition technique. In another aspect, the one or more high surface area shunt capacitors comprise thin films of TiN. In another aspect, the RF PA SiP device has a reduced signal loss when compared to an RF PA glass ceramic SiP. In another aspect, the RF PA SiP device has a loss of less than 50, 40, 30, 25, 20, 15, or 10% of the signal input versus a signal output. In another aspect, the RF PA SiP device has filters with a center frequency shift of less than/greater than 50, 40, 30, 25, 20, 15, or 10 MHz. In another aspect, the substrate is glass. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide. In another aspect, the method further comprises coating or depositing a passivation or coating on the RF PA integrated SiP device to protect the RF PA integrated SiP device from an environment. In another aspect, the conductive coils comprise copper. In another aspect, the RF PA integrated SiP device has a reduced signal loss when compared to existing RF PA integrated glass ceramic SiP. In another aspect, the RF PA SiP device has a loss of less than 50, 40, 30, 25, 20, 15, or 10% of the signal input versus a signal output. In another aspect, the iron core comprises melted or sintered iron particles, microparticles, or nanoparticles. In another aspect, a geometry of the RF PA integrated SiP device is substantially circular. In another aspect, the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the substrate is a photosensitive glass ceramic composite substrate comprising at least silica, lithium oxide, aluminum oxide, and cerium oxide.

In another embodiment, the present invention can include a radio frequency power amplifier integrated SiP device made by a method comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the integrated SiP to an antenna.

In another embodiment, the present invention can include a method of making a radio frequency power amplifier integrated system-in-a-package device comprising, consisting essentially of, or consisting of: forming on a substrate one or more conductive coils, wherein the one or more conductive coils are formed in, on, or about the substrate; etching an opening in the substrate; depositing iron particles in the opening; and connecting the conductive coils of the RF integrated SiP to an antenna.

In another embodiment, the present invention can include a method for fabricating of a RF PA integrated SiP on or in a glass ceramic comprising, consisting essentially of, or consisting of: obtaining a bottom layer or integrated passive device (IPD) base or substrate; exposing, baking, and etching one or more first through glass vias (TGVs); exposing and baking a high density (HD) capacitor cavity; filling the first TGVs with a metal; double side polish the substrate to a final thickness; patterning and depositing a first topside metal; depositing SiN on top of the first topside metal to form an insulator for a Metal-Insulator-Metal (MIM) capacitor; patterning and etching SiN to remove unwanted SiN from the substrate; depositing on a topside and a backside of the substrate a first metal plating base; patterning a photoresist on the topside and backside of the substrate; electroplating a second metal layer on the topside and backside of the substrate, wherein the second metal layer is thicker than the first metal plating base; removing the photoresist and etching the metal plating base; coating a third metal layer by Electroless Nickel Immersion Gold (ENIG) on the first substrate; etching a high density capacitor cavity in the first substrate; patterning and coating high density capacitor copper pillars with a dielectric layer; patterning and coating the high density capacitor dielectric with a fourth metal layer to make a MIM high density capacitor; obtaining a top layer, lid, or second substrate; exposing, baking, and etching one or more second TGVs in the second substrate; filling the second TGVs in the second substrate with metal; polishing both sides of the second substrate to a final thickness; depositing on a topside and a backside of the second substrate a metal plating base; patterning a photoresist on the metal plating base on the topside and backside of the second substrate; electroplating a fifth copper metal layer on the topside and backside of the second substrate; removing the photoresist and etching a second metal plating base; coating a sixth copper metal layer with ENIG; and bonding the first substrate to the second substrate using solder, adhesives, or Au/Au thermosonic bonding.

In some embodiments, the etchant is HF, in some embodiments the etchant is a combination of HF and additional ingredients, such as hydrochloric acid or nitric acid. The preferred wavelength of the ultraviolet light used for exposure is approximately 308-312 nm.

FIG. 4 shows a shift in the frequency of the signal from 300 MHz to 900 MHZ. This effectively triples the Video Transmission Bandwidth by placing the RF filter directly in either the source or drain of the RF PA integrated SiP.

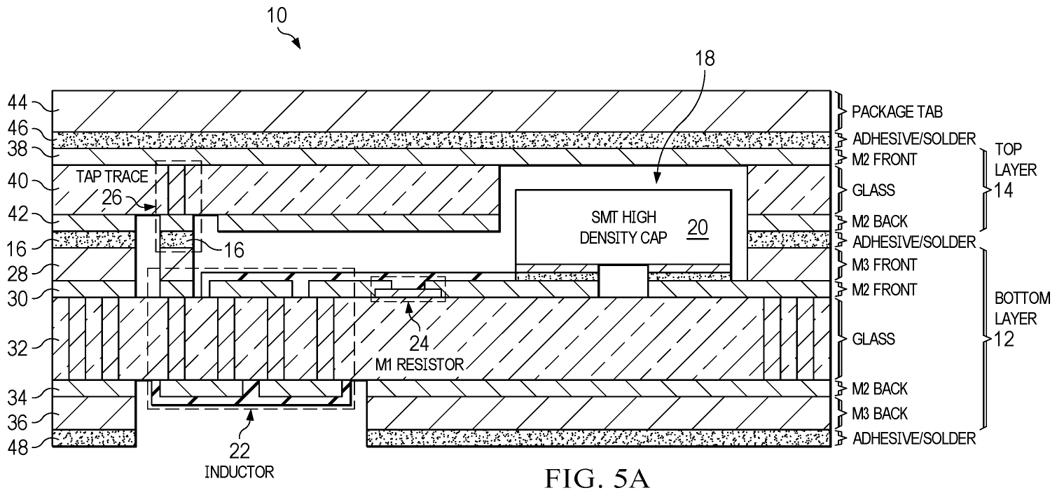

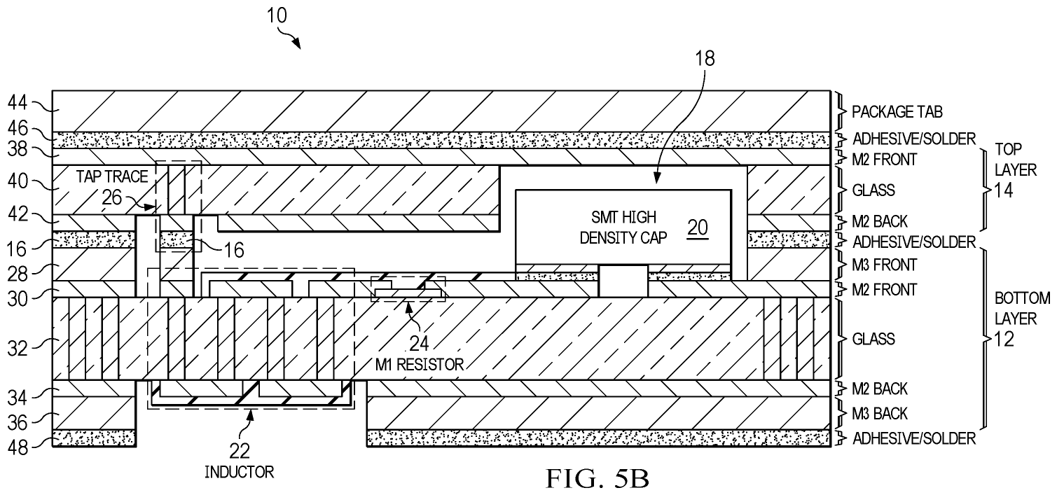

FIG. 5 shows an electrical schematic for a photodefinable glass RF PA SiP of the present invention with RF filter in either the source or drain of the GaN amplifier.

FIG. 5A shows one possible configuration of the RF PA SiP 10 with the SMT High Density Capacitor placed on top of the metal contact of the Drain/Source of the GaN. FIG. 5A shows the bottom layer 12, the top layer 14, the adhesive/solder layer 16, the air gap 18, the SMT high density capacitor 20, the inductor 22, the M1 resistor 24, and the tap trace 26. The bottom layer 12 is shown consisting of M3 front 28, M2 front 30, glass 1 32, M2 back 34, and M3 back 36. Top layer 14 is shown consisting of M2 front 38, glass 2 40, and M2 back 42. The RF PA SiP 10 is shown further comprising a package tab 44, an adhesive/solder layer 46, and adhesive/solder layer 48, and a PA flange 50.

FIG. 5B shows a cross section with the SMT High Density Capacitor placed on top of the metal contact of the Drain/Source of the GaN. FIG. 5B shows the RF PA SiP 10 including the bottom layer 12, the top layer 14, the adhesive/solder layer 16, the air gap 18, the SMT high density capacitor 20, the inductor 22, the M1 resistor 24, and the tap trace 26.

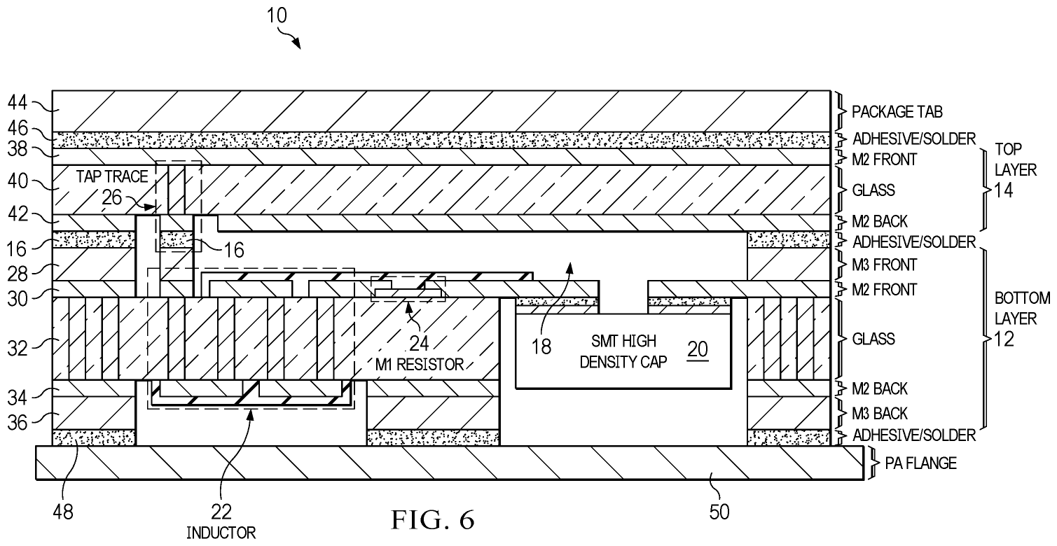

FIG. 6 shows a second configuration with the SMT-High Density Capacitor placed on bottom of the metal contact of the Drain/Source of the GaN. FIG. 5B shows the RF PA SiP 10 including the bottom layer 12, the top layer 14, the adhesive/solder layer 16, the air gap 18, the SMT high density capacitor 20, the inductor 22, the M1 resistor 24, and the tap trace 26.

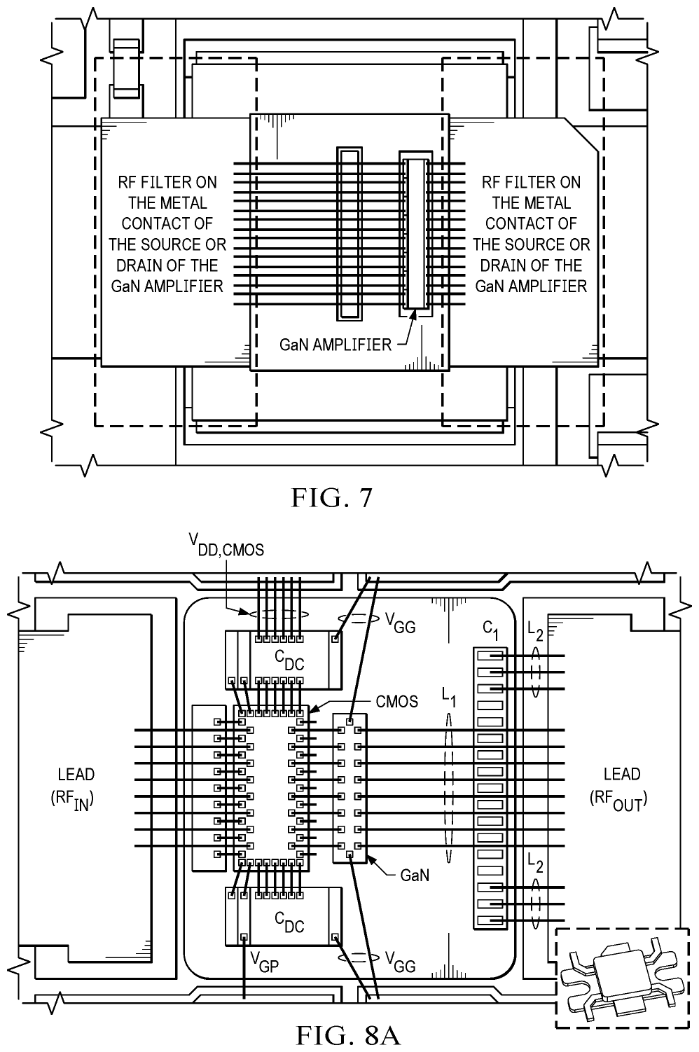

FIG. 7 shows the placement of the RF Filter in/on the source or drain of the GaN amplifier of the RF SiP.

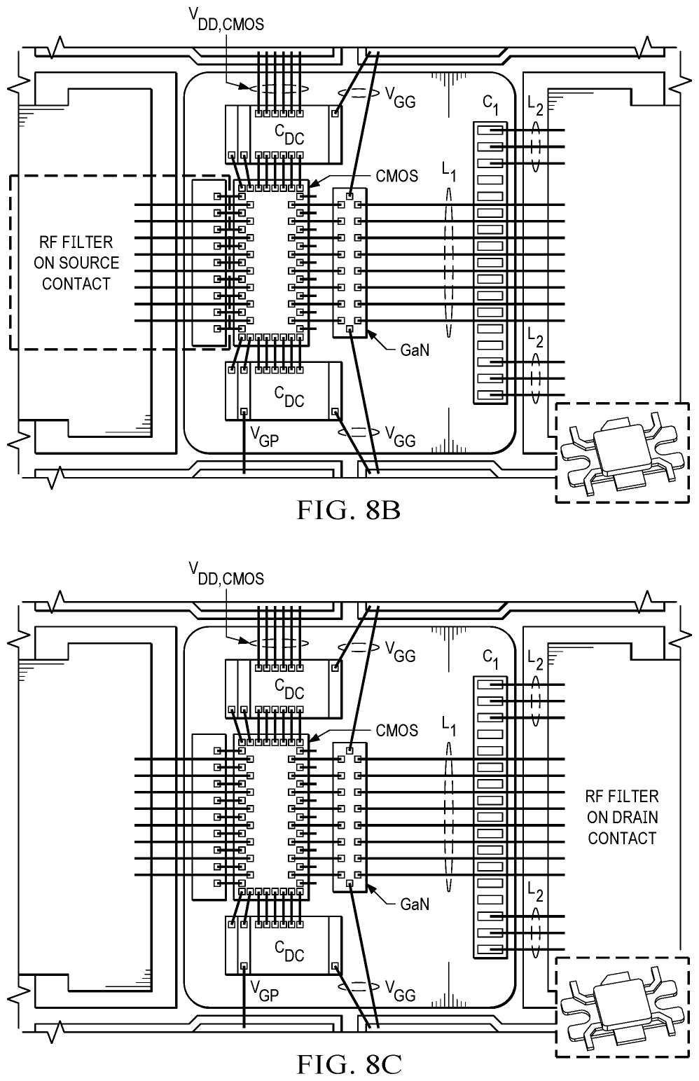

FIG. 8A shows a traditional RF Amplifier with no integrated filter in the SiP.

FIG. 8B shows an RF Amplifier with placement of the RF filter on the contact for the Source side of the GaN Amplifier. Minimum Capacitance: 3 nF.

FIG. 8C shows an RF Amplifier with placement of the RF filter on the contact for the Drain side of the GaN Amplifier. Minimum Capacitance: 3 nF.

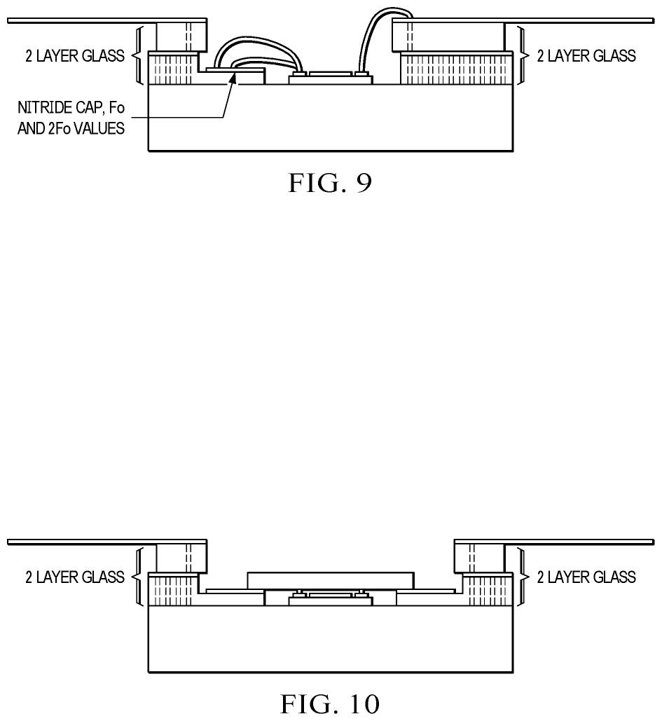

FIG. 9 shows a drawing of integration of SiP using wire bonds to connect semiconductor device(s) to IPDs, where the semiconductor can be a power amplifier or other semiconductor device.

FIG. 10 shows power amplifier of other semiconductor element with metalized Kapton™ replacement for bonding wire connectors to create a SiP. Gain dropped by 0.4 dB, P-3 dB increased by 0.2 dB and efficiency, and P-3 dB increased by 1.1%. This is probably due to a slight impedance shift and should be ignored. The ringframe can be extended to accommodate a DC bus tying all the capacitors to leads and/or bonding places.

Murata caps can be bonded inside the package and/or Murata 10 uF chip caps can attach outside the package. If the IR drop is low enough (metal beefiness high enough), DC can be supplied through the extra leads. IF DC is supplied via extra leads, the drain lead can be altered to incorporate a nitride based series capacitor to tune out the bond wire inductance (and be a DC block).

It is contemplated that any embodiment discussed in this specification can be implemented with respect to any method, kit, or composition of the invention, and vice versa. Furthermore, compositions of the invention can be used to achieve methods of the invention.

It will be understood that embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of.” As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step, or a limitation) or group of integers (e.g., feature(s), element(s), characteristic(s), property(ies), method/process step(s), or limitation(s)) only.

As used herein, the term “or combinations thereof” refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about,” “substantial,” or “substantially,” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the devices and/or methods disclosed and claimed herein can be made and executed without undue experimentation in light of the present disclosure. While the devices and/or methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope, and concept of the invention as defined by the appended claims.

Furthermore, no limitations are intended to the details of construction or design herein shown, other than as described in the claims below. It is therefore evident that the particular embodiments disclosed above may be altered or modified and all such variations are considered within the scope and spirit of the disclosure. Accordingly, the protection sought herein is as set forth in the claims below.

Modifications, additions, or omissions may be made to the systems and apparatuses described herein without departing from the scope of the invention. The components of the systems and apparatuses may be integrated or separated. Moreover, the operations of the systems and apparatuses may be performed by more, fewer, or other components. The methods may include more, fewer, or other steps. Additionally, steps may be performed in any suitable order.

To aid the Patent Office, and any readers of any patent issued on this application in interpreting the claims appended hereto, applicants wish to note that they do not intend any of the appended claims to invoke paragraph 6 of 35 U.S.C. § 112 as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

1.-58. (canceled)

59. A radio frequency power amplifier (RF PA) system-in-a-package (SiP) device comprising:
a substrate comprising one or more inductors, capacitors, and thin film resistors wherein the one or more are formed in, on, or about the substrate;
an opening in the substrate comprising an iron core, wherein the iron core is formed in the substrate after the formation is create a RF PA SiP in the substrate; and
one or more connectors, vias, resistors, capacitors, or other integrated circuits devices connected to create the RF PA SiP.

60. The device of claim 59, wherein at least one of:
the one or more inductors are one or more conductive coils that comprise copper; or
the one or more capacitors are one or more high surface area shunt capacitors.

61. The device of claim 60, wherein at least one of:
the one or more high surface area shunt capacitors comprise copper pillars coated with a thin film dielectric material and layer of copper; or
the one or more resistors comprise one or more high surface area shunt capacitors.

62. The device of claim 61, wherein at least one of:
the one or more high surface area shunt capacitors are formed using a thin film deposition technique; or
the one or more high surface area shunt capacitors comprise thin films of TiN.

63. The device of claim 59, wherein at least one of:
the RF PA SiP device has a reduced signal loss when compared to an RF PA glass ceramic SiP; or
the RF PA SiP device has a loss of less than 50, 40, 30, 25, 20, 15, or 10% of a signal input versus a signal output; or
the RF PA SiP device has filters with a center frequency shift of less than 80, 75, 70, 60, 50, 40, 30, 25, 20, 15, or 10 MHz.

64. The device of claim 59, wherein at least one of:
the substrate is glass;
the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂;
the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂;
the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to an unexposed portion is at least one of 10-20:1; 21-29:1; 30-45:1; 20-40:1; 41-45:1; and 30-50:1; or
the substrate is a photosensitive glass ceramic composite substrate comprising at least silica, lithium oxide, aluminum oxide, and cerium oxide.

65. The device of claim 59, further comprising at least one of:
a passivation or coating layer on the RF PA SiP device to protect the RF PA SiP device from an environment;
the connectors comprise copper, which can be connector coils;
the RF PA SiP device has a reduced signal loss when compared to existing RF PA glass ceramic SiP;
the RF PA SiP device has a loss of less than 50, 40, 30, 25, 20, 15, or 10% of a signal input versus a signal output;
a geometry of the RF PA SiP device is substantially circular; or
the iron core comprises melted or sintered iron particles, microparticles, or nanoparticles.

66. A radio frequency power amplifier (RF PA) system-in-a-package (SiP) device made by a method comprising:
forming on a substrate one or more conductive coils, wherein the one or more conductive coils are formed in, on, or about the substrate;
etching an opening in the substrate;
depositing iron particles in the opening; and
connecting the conductive coils of the RF PA SiP to an antenna.

67. A method for fabricating of a RF PA SiP on or in a glass ceramic comprising:
obtaining a bottom layer or integrated passive device (IPD) base or first substrate;
exposing, baking, and etching one or more first through glass vias (TGVs);
exposing and baking a high density (HD) capacitor cavity;
filling the first TGVs with a metal;
double side polish the substrate to a final thickness;
patterning and depositing a first topside metal;
depositing SiN on top of the first topside metal to form an insulator for a Metal-Insulator-Metal (MIM) capacitor;
patterning and etching SiN to remove unwanted SiN from the substrate;
depositing on a topside and a backside of the substrate a first metal plating base;
patterning a photoresist on the topside and backside of the substrate;
electroplating a second metal layer on the topside and backside of the substrate, wherein the second metal layer is thicker than the first metal plating base;
removing the photoresist and etching the metal plating base;
coating a third metal layer by Electroless Nickel Immersion Gold (ENIG) on the first substrate;
etching a high density capacitor cavity in the first substrate;
patterning and coating high density capacitor copper pillars with a dielectric layer;
patterning and coating the high density capacitor dielectric with a fourth metal layer to make a MIM high density capacitor;
obtaining a top layer, lid, or second substrate;
exposing, baking, and etching one or more second TGVs in the second substrate;
filling the second TGVs in the second substrate with metal;
polishing both sides of the second substrate to a final thickness;
depositing on a topside and a backside of the second substrate a metal plating base;
patterning a photoresist on the metal plating base on the topside and backside of the second substrate;
electroplating a fifth copper metal layer on the topside and backside of the second substrate;
removing the photoresist and etching a second metal plating base;
coating a sixth copper metal layer with ENIG; and
bonding the first substrate to the second substrate using solder, adhesives, or Au/Au thermosonic bonding.

68. The method of claim 67, wherein at least one of:
the metal is copper, silver, gold, platinum, titanium, aluminum, or alloys thereof;
the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂;
the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂;
the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to an unexposed portion is at least one of 10-20:1; 21-29:1; 30-45:1; 20-40:1; 41-45:1; and 30-50:1; or
the substrate is a photosensitive glass ceramic composite substrate comprising at least silica, lithium oxide, aluminum oxide, and cerium oxide.

69. A radio frequency integrated system-in-a-package (SiP) device comprising with the RF filter monolithically integrated into the source or drain contact of the GaN transistor comprising:
a substrate comprising one or more inductors, capacitors, and thin film resistors wherein the one or more are formed in, on, or about the substrate; and
one or more connectors, vias, resistors, inductors, capacitors, or other integrated circuits devices connected to create the RF integrated SiP.

70. The device of claim 69, wherein at least one of:
the one or more inductors are one or more conductive coils that comprise copper;
the one or more capacitors are one or more high surface area shunt capacitors; or
the one or more MIM capacitors are one or more high surface area shunt capacitors.

71. The device of claim 70, wherein at least one of:
the one or more high surface area shunt capacitors comprise semiconductor doped conductive pillars coated with a thin film dielectric material and layer of copper;
the one or more high surface area shunt capacitors comprise copper pillars coated with a thin film dielectric material and layer of copper; or
the one or more resistors comprise one or more high surface area shunt capacitors.

72. The device of claim 71, wherein at least one of:
the one or more high surface area shunt capacitors are formed using a thin film deposition technique; or
wherein the one or more high surface area shunt capacitors comprise thin films of SiN or other dielectric material.

73. The device of claim 69, wherein at least one of:
the RF PA SiP device has a reduced signal loss when compared to an RF PA glass ceramic SiP;
the RF integrated SiP device has a loss of less than 50, 40, 30, 25, 20, 15, or 10% of a signal input versus a signal output;
the RF PA SiP device increases bandwidth the video/communications bandwidth a minimum 10% to greater than 300%;

74. The device of claim 69, further comprising a passivation or coating layer on the RF PA SiP device to protect the RF PA SiP device from an environment.

75. The device of claim 69, wherein at least one of:
the substrate is glass;
the substrate is a photosensitive glass ceramic composite substrate comprising at least silica, lithium oxide, aluminum oxide, and cerium oxide;
the connectors comprise copper, which can be connector coils;
the RF PA SiP device has a reduced signal loss when compared to existing RF PA glass ceramic SiP;
the RF PA SiP device has a loss of less than 50, 40, 30, 25, 20, 15, or 10% of a signal input versus a signal output;
a geometry of the RF PA SiP device is substantially circular; or
the iron core comprises melted or sintered iron particles, microparticles, or nanoparticles.

76. A radio frequency power amplifier (RF PA) system-in-a-package (SiP) device made by a method comprising:
forming on a substrate one or more conductive coils, wherein the one or more conductive coils are formed in, on, or about the substrate;
etching an opening in the substrate;
depositing iron particles in the opening; and
connecting the conductive coils of the RF PA SiP to an antenna.

77. A method for fabricating of a RF PA SiP on or in a glass ceramic comprising:
obtaining a bottom layer or integrated passive device (IPD) base or first substrate;
exposing, baking, and etching one or more first through glass vias (TGVs);
exposing and baking a high density (HD) capacitor cavity;
filling the first TGVs with a metal;
double side polishing the substrate to a final thickness;
patterning and depositing a first topside metal;
depositing SiN on top of the first topside metal to form an insulator for a Metal-Insulator-Metal (MIM) capacitor;
patterning and etching SiN to remove unwanted SiN from the substrate;
depositing on a topside and a backside of the substrate a first metal plating base;
patterning a photoresist on the topside and backside of the substrate;
electroplating a second metal layer on the topside and backside of the substrate, wherein the second metal layer is thicker than the first metal plating base;
removing the photoresist and etching the metal plating base;
coating a third metal layer by Electroless Nickel Immersion Gold (ENIG) on the first substrate;
etching a high density capacitor cavity in the first substrate;
patterning and coating high density capacitor copper pillars with a dielectric layer;
patterning and coating the high density capacitor dielectric with a fourth metal layer to make a MIM high density capacitor;
obtaining a top layer, lid, or second substrate;
exposing, baking, and etching one or more second TGVs in the second substrate;
filling the second TGVs in the second substrate with metal;
polishing both sides of the second substrate to a final thickness;
depositing on a topside and a backside of the second substrate a metal plating base;
patterning a photoresist on the metal plating base on the topside and backside of the second substrate;
electroplating a fifth copper metal layer on the topside and backside of the second substrate;
removing the photoresist and etching a second metal plating base;
coating a sixth copper metal layer with ENIG; and
bonding the first substrate to the second substrate using solder, adhesives, or Au/Au thermosonic bonding.

78. The method of claim 77, wherein the metal is copper, silver, gold, platinum, titanium, aluminum, or alloys thereof.

79. The method of claim 77, wherein at least one of:
wherein the substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂;
wherein the substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂;
wherein the substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to an unexposed portion is at least one of 10-20:1; 21-29:1; 30-45:1; 20-40:1; 41-45:1; and 30-50:1; or
wherein the substrate is a photosensitive glass ceramic composite substrate comprising at least silica, lithium oxide, aluminum oxide, and cerium oxide.
